(19) United States
(12) Patent Application Publication
(10) Pub. No.: US 2012/0190211 A1
(43) Pub. Date: Jul. 26, 2012

(54) FILM FORMING METHOD, SEMICONDUCTOR DEVICE MANUFACTURING METHOD, INSULATING FILM AND SEMICONDUCTOR DEVICE

(75) Inventors: Hirokazu Ueda, Amagasaki (JP); Yusuke Ohsawa, Amagasaki (JP); Masahiro Horigome, Nirasaki (JP)

(73) Assignee: TOKYO ELECTRON LIMITED, Tokyo (JP)

(21) Appl. No.: 13/496,563

(22) PCT Filed: Sep. 9, 2010
(86) PCT No.: PCT/JP2010/065531

§ 371 Date: Apr. 10, 2012

(30) Foreign Application Priority Data
Sep. 17, 2009 (JP) 2009-215610
Nov. 10, 2009 (JP) 2009-257056

(51) Int. Cl. H01L 21/31; H01L 21/30

(52) U.S. Cl. 438/778; 438/758; 257/E21.24; 257/E21.211

(57) ABSTRACT

In a film forming method, firstly, a processing target substrate W as a base of a semiconductor device is held on a mounting table 34 by an electrostatic chuck. Then, a film forming gas is adsorbed onto the processing target substrate W (a gas adsorption process) ((A) of FIG. 6). Thereafter, the inside of the processing chamber 32 is evacuated in order to remove residues of the film forming gas ((B) of FIG. 6). Upon the completion of the first exhaust process, a plasma process using microwave is performed ((C) of FIG. 6). Upon the completion of the plasma process, the inside of the processing chamber 32 is evacuated in order to remove an unreacted reactant gas and the like ((D) of FIG. 6). These series of steps (A) to (D) are repeated in this sequence until a desired film thickness is obtained.

### TECHNICAL FIELD

The present disclosure relates to a film forming method, a semiconductor device manufacturing method, an insulating film and a semiconductor device. More particularly, the present disclosure relates to a semiconductor device manufacturing method and a film forming method using a plasma process, and also relates to a semiconductor device and an insulating film formed by the plasma process.

### BACKGROUND ART

Conventionally, when forming an insulating layer having high pressure resistance property or excellent leak property against a gate oxide film of a semiconductor device represented as a LSI (Large Scale Integrated circuit), a CCD (Charge Coupled Device) or a MOS (Metal Oxide Semiconductor) transistor, a thermal CVD (Chemical Vapor Deposition) method is generally used. However, if a silicon oxide having high insulation property is formed by the thermal CVD method, a silicon substrate needs to be exposed to a high temperature. In this case, if a conductive layer is formed on the silicon substrate by using a material having a relatively low melting point, such as metal having a low melting point, or a high molecular compound, the metal having a low melting point may be melted. As a method for solving these problem and efficiently forming a high-quality film, a PE-ALD (Plasma-Enhanced ALD) method has drawn attention (May 15 2008 ASM Semi Mfg China ALd Article.Pdf (Non-Patent Document 1).

Non-Patent Document 1: May 15 2008 ASM Semi Mfg China ALd Article.Pdf

### DISCLOSURE OF THE INVENTION

### Problems to be Solved by the Invention

Here, if a gate oxide film of a MOS transistor is formed by the method described in Non-Patent Document 1 by using general plasma energy, e.g., parallel-plate type plasma or ICP (Inductively-coupled Plasma), electric charges may be accumulated in, e.g., the gate oxide film of the MOS transistor or an adjacent layer. As a result, plasma damage such as charge-up damage may be inflicted on the gate oxide film. If the MOS transistor suffers the plasma damage, a Vth (threshold voltage) shift may become non-uniform or a current driving capacity may be reduced, resulting in degradation of the MOS transistor due to deterioration in insulation property thereof.

Further, since the film formation is performed at a relatively high temperature by the aforementioned CVD method, there also be caused the following problems as well as the mentioned problem that the metal having a low melting point is melted. That is, for a shape having a high aspect ratio or a shape having a microscopic stepped portion, it may be very difficult to form a film so as to cover the shape completely and poor step coverage is expected. Accordingly, high quality such as high leak property may not be achieved, and it may become difficult to obtain a semiconductor device having low power consumption or high speed.

In view of the foregoing, illustrative embodiment provide a film forming method capable of forming a high-quality film.

Illustrative embodiments also provide a semiconductor device manufacturing method for manufacturing a semiconductor device having a high-quality film.

Illustrative embodiments also provide an insulating film having high insulation property. Further, illustrative embodiments also provide a semiconductor device including an insulating film having high insulation property.

### Means for Solving the Problems

In accordance with one aspect of an illustrative embodiment, there is provided a film forming method for forming a film on a processing target substrate. The film forming method includes a gas adsorption process for forming an adsorption layer on the processing target substrate by adsorbing a film forming gas on the processing target substrate; and a plasma process for performing a plasma process on the adsorption layer by microwave plasma after the gas adsorption process.

In accordance with this film forming method, even if the processing target substrate has a shape having a high aspect ratio or a microscopic stepped portion, it is possible to form a film so as to cover the shape completely by forming the adsorption layer on the processing target substrate by adsorbing a film forming gas on the processing target substrate. Further, since the plasma process is performed by the microwave plasma, plasma damage can be greatly reduced in the film forming process. Accordingly, in accordance with the film forming method, a high-quality film can be formed.

The film may be an insulating film.

The gas adsorption process may include a process for adsorbing a film forming gas containing silicon atoms on the processing target substrate.

The gas adsorption process may further include a process for supplying a film forming gas containing BTBAS (bis-tertiaryl-buthyl-amino-silane) onto the processing target substrate.

The plasma process may include a process for performing an oxidation or a nitrification on the adsorption layer formed through the gas desorption process by plasma.

The microwave plasma may be generated by a radial line slot antenna (RLSA).

The plasma process may be performed by the microwave plasma having an electron temperature lower than about 1.5 eV and an electron density higher than about 1×10¹¹ cm⁻³ in a vicinity of a surface of the processing target substrate.

The plasma process may be performed at a pressure equal to or lower than about 200 mTorr.

The gas adsorption process may include a process for forming the adsorption layer after adjusting a volume of a region above the processing target substrate.

The film forming method may further include an exhaust process for evacuating a region above the processing target substrate between the gas adsorption process and the plasma process. Further, the film forming method may further include an exhaust process for evacuating a region above the processing target substrate after the plasma process.

In accordance with another aspect of an illustrative embodiment, there is provided a semiconductor device manufacturing method including a film forming method for forming a film on a processing target substrate. The film forming method may include a gas adsorption process for forming an adsorption layer on the processing target substrate by adsorbing a film forming gas on the processing target substrate; and a plasma process for performing a plasma process on the adsorption layer by microwave plasma after the gas adsorption process.

In accordance with still another aspect of the illustrative embodiment, there is provided an insulating film formed on a processing target substrate. The insulating film may be formed by forming an adsorption layer on the processing target substrate by adsorbing a film forming gas on the processing target substrate; and performing a plasma process on the adsorption layer by microwave plasma.

Here, it is desirable to set a fixed electrical charge density (Qss/q) in the insulating film to have a small value. Further, after a H₂ sintering process which is used in an actual LSI manufacturing process, the fixed electrical charge density (Qss/q) in the insulating film may be equal to or lower than about 2.5×10¹¹ (cm⁻²). Such the fixed electrical charge density (Qss/q) in the insulating may be equal to a fixed electrical charge density in a thermal oxidation film formed by a wet oxidation method.

Further, an interface state density (Dit) of the insulating film may be equal to or lower than about 5.0×10¹⁰ (cm⁻²eV⁻¹).

The insulating film may be a SiO₂ film.

In accordance with still another aspect of the illustrative embodiment, there is provided a semiconductor device having an insulating film. The insulating film may be formed by forming an adsorption layer on the processing target substrate by adsorbing a film forming gas on the processing target substrate; and performing a plasma process on the adsorption layer by microwave plasma.

In accordance with still another aspect of the illustrative embodiment, there is provided a film forming method for forming a film on a processing target substrate. The film forming method includes a gas adsorption process for forming an adsorption layer on the processing target substrate by adsorbing a film forming gas on the processing target substrate; and a plasma process for performing a plasma process on the adsorption layer by microwave plasma after the gas adsorption process. The plasma process may be performed at a pressure equal or lower than about 400 mTorr.

In accordance with this film forming method, it is possible to form a film having high insulation property.

In accordance with still another aspect of the illustrative embodiment, there is provided an insulating film formed on a processing target substrate and the insulating film serves as a gate insulating film. The insulating film may be formed by forming an adsorption layer on the processing target substrate by adsorbing a film forming gas on the processing target substrate; and performing a plasma process on the adsorption layer by microwave plasma at a pressure equal or lower than about 400 mTorr.

### Effect of the Invention

In accordance with a film forming method of illustrative embodiments, even if a processing target substrate has a shape having a high aspect ratio or a microscopic stepped portion, it is possible to form a film so as to cover the shape completely by forming a adsorption layer on the processing target substrate by adsorbing a film forming gas on the processing target substrate. Further, since a plasma process is performed by microwave plasma, plasma damage can be greatly reduced in a film forming process. Accordingly, in accordance with the film forming method of the illustrative embodiments, a high-quality film can be formed.

Further, in accordance with a semiconductor device manufacturing method of the illustrative embodiments, a semiconductor device having a high-quality film can be manufactured.

Further, in accordance with the illustrative embodiments, an insulating film has high insulation property.

Furthermore, in accordance with the illustrative embodiments, the semiconductor device includes an insulating film having high insulation property.

### BRIEF DESCRIPTION OF THE DRAWINGS

FIG. 1 is a schematic cross sectional view illustrating a part of a MOS semiconductor device.

FIG. 2 is a schematic cross sectional view illustrating major components of a plasma processing apparatus used in a semiconductor device manufacturing method in accordance with an illustrative embodiment.

FIG. 3 illustrates a slot antenna plate in the plasma processing apparatus of FIG. 2, when viewed in a plate-thickness direction.

FIG. 4 is a graph showing a relationship between a distance from a bottom surface of a dielectric window and an electron temperature of plasma.

FIG. 5 is a graph showing a relationship between a distance from a bottom surface of the dielectric window and an electron density of plasma.

FIG. 6 is a flowchart showing a representative process for forming a film in the plasma processing apparatus of FIG. 2.

FIG. 7 is a graph showing a relationship between a gas flow rate in an entire of the processing chamber and time for reaching a certain pressure.

FIG. 8 is a graph showing a relationship between a gas flow rate and time required to reach a certain pressure in a small-volume area formed above a mounting table.

FIG. 9 is an enlarged cross sectional view illustrating a vicinity of a device isolation region.

FIG. 10 is a micrograph showing an enlarged cross sectional view of a liner film formed by PE-ALD method using RLSA when an aspect ratio of a trench is about 6.

FIG. 11 is a micrograph showing an enlarged cross sectional view of a liner film formed by PE-ALD method using RLSA when an aspect ratio of a trench is about 3.

FIG. 12 is a graph showing TDS integral values of films.

FIG. 13 is a graph showing etching rates of films.

FIG. 14 is a graph showing Q-SIMS values of films.

FIG. 15 is a graph showing I-V curves of films.

FIG. 16 is a schematic cross sectional view illustrating a flat MOS used to obtain the I-V curves shown FIG. 15.

FIG. 17 is a graph showing Weibull plots of Qbd of films.

FIG. 18 is a graph showing fixed electrical charges densities in films.

FIG. 19 is a graph showing interface state densities (Dit) of films.

FIG. 20 is a graph showing measurement positions of TZDB (Time Zero Dielectric Breakdown) in the flat MOS capacitor shown in FIG. 16.

FIG. 21 is a graph showing TZDB characteristics in films measured at the measurement positions shown in FIG. 20.

### BEST MODE FOR CARRYING OUT THE INVENTION

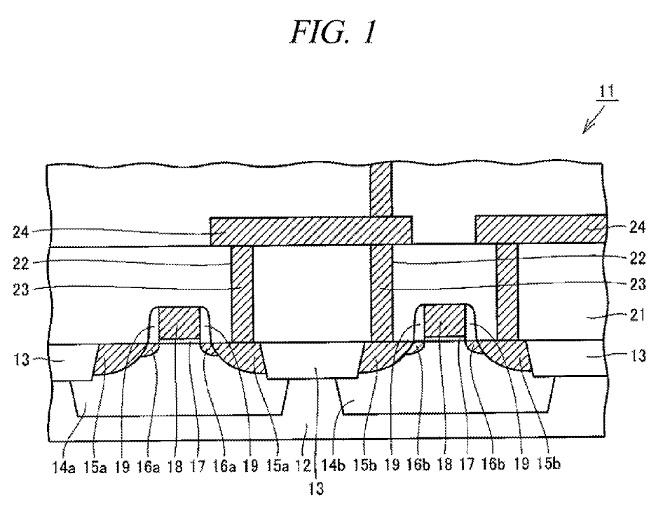

Hereinafter, illustrative embodiments will be described with reference to the accompanying drawings. First, a structure of a semiconductor device in accordance with an illustrative embodiment will be explained. FIG. 1 is a schematic cross sectional view illustrating a part of a MOS semiconductor device in accordance with an illustrative embodiment. In FIG. 1, a conductive layer of the MOS semiconductor device is hatched.

Referring to FIG. 1, a MOS semiconductor device 11 includes, a silicon substrate 12 on which device isolation regions 13, p-wells 14a, n-wells 14b, high-concentration n-type impurity diffusion regions 15a, high-concentration p-type impurity diffusion regions 15b, n-type impurity diffusion regions 16a, p-type impurity diffusion regions 16b and gate oxide films 17 are provided. One of the high-concentration n-type impurity diffusion regions 15a and the high-concentration p-type impurity diffusion regions 15b provided with the gate oxide films 17 therebetween serves as a drain, and the other one serves as a source.

Further, gate electrodes 18 formed of a conductive layer are provided on the gate oxide films 17, and gate sidewalls 19 formed of insulating films are provided at side portions of the gate electrodes 18. Furthermore, in the insulating films 21, contact holes 22 connected to the high-concentration n-type impurity diffusion regions 15a and the high-concentration p-type impurity diffusion regions 15b are formed. Within the contact holes 22, embedded electrodes 23 are provided. On the contact holes 22, metal wiring layers 24 formed conductive layers are provided. Furthermore interlayer insulating films (not shown) formed as insulating layers and metal wiring layers formed as conductive layers are provided alternately and finally, pads (not shown) as contact points with the outside are provided. The MOS semiconductor device 11 is configured as described above.

In the semiconductor device in accordance with the illustrative embodiment, as will be described later, an adsorption layer is formed on a processing target substrate by adsorbing a film forming gas on the processing target substrate. Further, a silicon oxide film, e.g., a gate oxide film, formed by performing a plasma process using a process using microwave plasma on the adsorption layer such is formed. Furthermore, an insulating film in accordance with the illustrative embodiment is a silicon oxide film forming the gate oxide film. The insulating film is formed by forming a adsorption layer by adsorbing a film gas on the target substrate and by performing a plasma process with microwave plasma on the adsorption layer.

Now, a configuration and an operation of a plasma processing apparatus used in a semiconductor device manufacturing method in accordance with an illustrative embodiment will be explained.

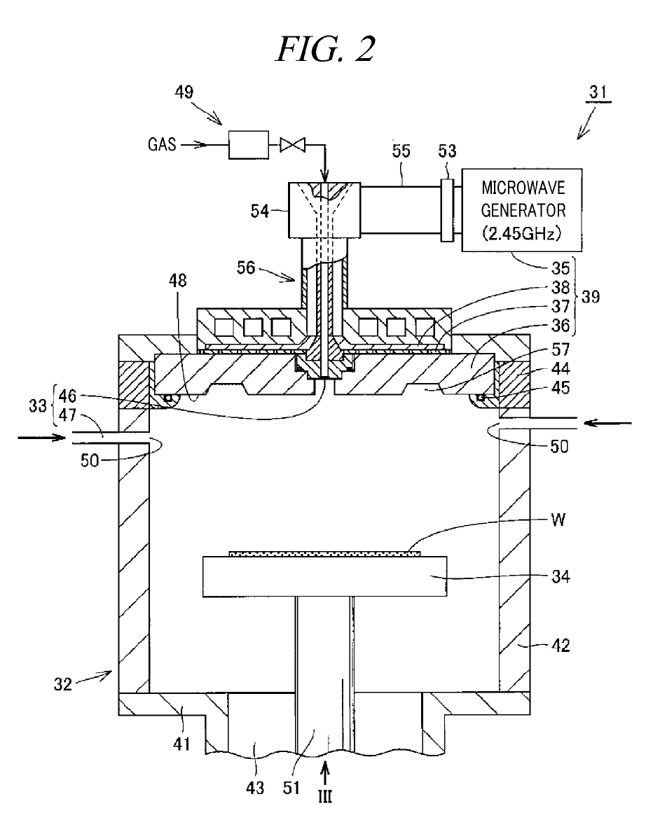

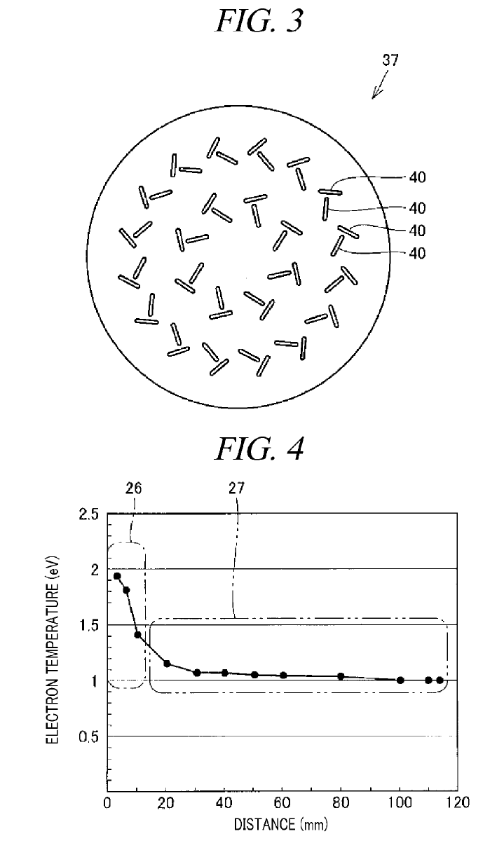

FIG. 2 is a schematic cross sectional view illustrating major components of a plasma processing apparatus used in the semiconductor device manufacturing method in accordance with the illustrative embodiment. FIG. 3 illustrates a slot antenna plate provided in the plasma processing apparatus of FIG. 2 when viewed from a lower side, i.e., from a direction of an arrow III of FIG. 2. In FIG. 2, hatching for some components is omitted for easy understanding.

Referring to FIGS. 2 and 3, a plasma processing apparatus 31 includes a processing chamber 32; a plasma processing gas supply unit 33; a circular plate-shaped mounting table 34; a plasma generating device 39; and a control unit (not shown). A plasma process is performed on a processing target substrate W in the processing chamber 32, and the plasma processing gas supply unit 33 is configured to supply a reactant gas for a plasma process into the processing chamber 32. Further, the circular plate-shaped mounting table 34 is configured to mount thereon the processing target substrate W, and the plasma generating device 39 is configured to generate plasma within the processing chamber 32. Here, the control unit is configured to control an overall of the plasma processing apparatus 31. By way of example, the control unit controls a gas flow rate in the plasma processing gas supply unit 33, an internal pressure in the processing chamber 32, and the like.

The processing chamber 32 includes a bottom portion 41 positioned below the mounting table 34 and a sidewall 42 upwardly extending from an outer periphery of the bottom portion 41. The sidewall 42 has a substantially cylindrical shape. A gas exhaust hole 43 for gas exhaust is formed in a part of the bottom portion 41 of the processing chamber 32. A top of the processing chamber 32 is opened, and the processing chamber 32 can be hermetically sealed by a cover 44 placed on the top of the processing chamber 32, a dielectric window 36 to be described later and an O-ring 45 serving as a sealing member between the dielectric window 36 and the cover 44.

The plasma processing gas supply unit 33 includes a first plasma processing gas supply unit 46 for discharging a gas on a center of the processing target substrate W; and a second plasma processing gas supply unit 47 for discharging a gas from an outside of the processing target substrate W. The first plasma processing gas supply unit 46 is provided at a center of the dielectric window 36 in a radial direction and is positioned at an upper position of the dielectric window 36 from a bottom surface 48 thereof facing the mounting table 34. The first plasma processing gas supply unit 46 supplies a plasma processing gas while controlling a flow rate of the plasma processing gas by a gas supply system 49 connected to the first plasma processing gas supply unit 46. The second plasma processing gas supply unit 47 includes a multiple number of plasma processing gas supply holes 50 formed in a part of an upper portion of the sidewall 42. From the plasma processing gas supply holes 50, a plasma processing gas is supplied into the processing chamber 32. The multiple numbers of plasma processing gas supply holes 50 are arranged at a regular distance along a circumference of the sidewall 42. The same kind of plasma processing gas is supplied into the first and second plasma processing gas supply units 46 and 47 from a single reactant gas supply source.

The mounting table 34 is capable of holding thereon the processing target substrate W by an electrostatic chuck (not shown). Further, the mounting table 34 can be controlled to a desired temperature by a temperature control device (not shown) provided therein. The mounting table 34 is supported on an insulating cylindrical support 51 extending from below the bottom portion 41 vertically upward. The gas exhaust hole 43 is formed in a part of the bottom portion 41 of the processing chamber 32 along the periphery of the cylindrical support 51. A bottom portion of the annular gas exhaust hole 43 is connected with a gas exhaust device (not shown) via a gas exhaust pipe (not shown). The gas exhaust device has a vacuum pump such as a turbo molecular pump. The inside of the processing chamber 32 can be depressurized to a desired vacuum level by the gas exhaust device.

The plasma generating device 39 is positioned at outside of the processing chamber 32, and the plasma generating device 39 includes a microwave generator 35, the dielectric window 36, a slot antenna plate 37 and a dielectric member 38. The microwave generator 35 generates microwave for exciting plasma. The dielectric window 36 is provided at a position facing the mounting table 34 and serves to introduce the microwave generated by the microwave generator 35 into the processing chamber 32. The slot antenna plate 37 provided on the dielectric window 36 has a multiple number of slot holes 40 and serves to radiate the microwave to the dielectric window 36. The dielectric member 38 is placed on the slot antenna plate 37 and serves to propagate the microwave introduced from a coaxial waveguide 56 to be described later in a radial direction.

The microwave generator 35 having a matching device 53 is connected to an upper portion of the coaxial waveguide 56 for introducing the microwave via a mode converter 54 and a waveguide 55. By way of example, the microwave of a TE mode generated by the microwave generator 35 is converted to a TEM mode by the mode converter 54 after it passes through the waveguide 55. Then, the microwave of the TEM mode is propagated into the coaxial waveguide 56. A frequency of the microwave generated by the microwave generator 35 is, for example, about 2.45 GHz.

The dielectric window 36 has a substantially circular plate shape and is made of a dielectric material. Formed on a bottom surface 48 of the dielectric window 36 is a ring-shaped tapered recess 57 for facilitating generation of a standing wave by the introduced microwave. Due to the recess 57, plasma can be efficiently generated under the dielectric window 36 by the microwave. Further, the dielectric window 36 may be made of a material such as, but not limited to, quartz or alumina.

The slot antenna plate 37 has a thin circular plate shape. The multiple number of slot holes 40 have elongated hole shapes. As illustrated in FIG. 3, every pair of two adjacent slot holes 40 are arranged so as to be orthogonal to each other in a substantially T-shape. A multiplicity of pairs of slot holes 40 are arranged at a regular distance along a circumference of the slot antenna plate 37. Further, a multiplicity of pairs of slot holes 40 are also arranged at a regular distance in a radial direction.

The microwave generated by the microwave generator 35 is propagated to the dielectric member 38 through the coaxial waveguide 56 and is then radiated to the dielectric window 36 through the multiple numbers of slot holes 40 of the slot antenna plate 37. Then, the microwave transmitted through the dielectric window 36 generates an electric field directly under the dielectric window 36, so that plasma is generated within the processing chamber 32. That is, microwave plasma supplied for a process within the plasma processing apparatus 31 is generated by a RLSA (Radial Line Slot Antenna) including the slot antenna plate 37 and the dielectric member 38 having the above-described configurations.

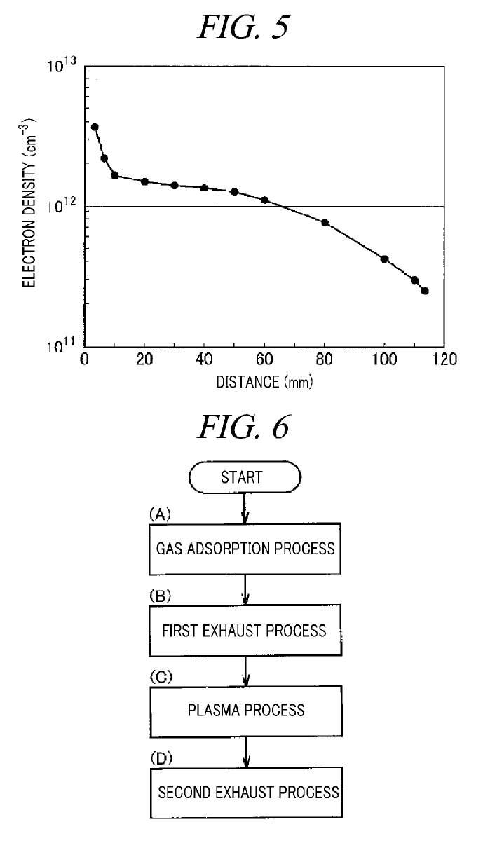

FIG. 4 is a graph showing a relationship between a distance from the bottom surface 48 of the dielectric window 36 within the processing chamber 32 and an electron temperature of plasma generated within the plasma processing apparatus 31. FIG. 5 is a graph showing a relationship between a distance from the bottom surface 48 of the dielectric window 36 within the processing chamber 32 and an electron density of plasma generated within the plasma processing apparatus 31.

Referring to FIGS. 4 and 5, a region directly under the dielectric window 36, to be specific, a region 26 up to a distance of about 10 mm from the bottom surface 48 of the dielectric window 36, as indicated by a dashed dotted line, is so-called a plasma generation region. In this region 26, an electron temperature of plasma is high and an electron density of the plasma is higher than about 1×10¹² cm⁻³. Meanwhile, a region 27 beyond a distance of about 10 mm from the bottom surface 48 of the dielectric window 36 as indicated by a dashed double-dotted line is called a plasma diffusion region. In this region 27, an electron temperature of the plasma is in the range from about 1.0 eV to about 1.3 eV, lower than at least about 1.5 eV. Further, in this region 27, an electron density of the plasma is about 1×10¹² cm⁻³, higher than at least about 1×10¹¹ cm⁻³. In the processing chamber 32 of the plasma processing apparatus 31, a processing gas is excited by a microwave and a plasma state as specified above is obtained therein. A plasma process on a processing target substrate W to be described later is performed in the plasma diffusion region. That is, the plasma process is performed by using microwave plasma having an electron temperature lower than about 1.5 eV and an electron density higher than about 1×10¹¹ cm⁻³ in a vicinity of a surface of the processing target substrate.

Now, a method for manufacturing a semiconductor device including an insulating film by the plasma processing apparatus 31 will be described with reference to FIGS. 1 to 6 and Table 1. FIG. 6 is a flowchart illustrating a sequence of a representative process performed when a film is formed on a processing target substrate by the plasma processing apparatus shown in FIG. 2, for example. In Table 1, processes and processing conditions therefore are specified. In a plasma process to be described later, a temperature of the mounting table 34 is set to be in the range of about 300° C. to about 400° C.

TABLE 1

| Step | (A) | (B) | (C) | (D) |
|---|---|---|---|---|
| Process | Gas | First | Plasma | Second |
| | adsorption | exhaust | process | exhaust |
| | process | process | | process |
| Pressure | 1 | 2> | 1 | 2> |
| (Torr) | | | | |
| Ar gas flow | 540 | 540 | 540 | 540 |
| rate (sccm) | | | | |
| O₂ gas flow | 0 | 0 | 60 | 0 |
| rate (sccm) | | | | |
| Precursor flow | 30 | 0 | 0 | 0 |
| rate (sccm) | | | | |
| Microwave | 0 | 0 | 3 | 0 |
| output (kW) | | | | |

Referring to Table 1 and FIGS. 1 to 6, firstly, a processing target substrate W as a base of a semiconductor device is held on the mounting table 34 by the electrostatic chuck.

Then, a film forming gas is adsorbed onto the processing target substrate W (a gas adsorption process) ((A) of FIG. 6). Here, for example, by supplying the film forming gas onto the processing target substrate W while controlling the inside of the processing chamber 32 to have a pressure specified in Table 1, the film forming gas is adsorbed onto the processing target substrate W. The film forming gas is supplied from the plasma processing gas supply unit 33. In this case, as a precursor, a film forming gas containing silicon atoms such as a film forming gas containing BTBAS (Bis-Tertiary-Buthyl-Amino-Silane) is supplied, as shown in Table 1.

Thereafter, in step (B) of Table 1, as a first exhaust process, the inside of the processing chamber 32 is evacuated in order to remove residues of the film forming gas ((B) of FIG. 6). The processing chamber 32 is evacuated through the gas exhaust hole 43 by using the gas exhaust device.

Upon the completion of the first exhaust process, in step (C) of Table 1, a plasma process using microwave is performed ((C) of FIG. 6). To be specific, a plasma processing gas including a reactant gas and a gas for plasma excitation is supplied into the processing chamber 32 from the plasma processing gas supply unit 33. In the illustrative embodiment, as the reactant gas, an oxygen gas is used. Within the processing chamber 32, plasma is generated by the plasma generating device 39, and a plasma process is performed on an adsorption gas layer by the microwave plasma. As a result, a silicon oxide film is formed by the plasma process with oxygen radicals excited by the microwave. Here, a temperature of the mounting table 34 is set to be about 400° C.

Upon the completion of the plasma process, in step (D) of Table 1, as a second exhaust process, the inside of the processing chamber 32 is evacuated in order to remove an unreacted reactant gas and the like ((D) of FIG. 6). These series of steps (A) to (D) are repeated in this sequence until a desired film thickness is obtained. An actual film thickness is selected within a range, for example, from about 1 nm to about 500 nm. Through the above-described processes, the silicon oxide film is formed on the processing target substrate W. Thereafter, an etching process is repeatedly performed on desired positions on the processing target substrate W, so that a semiconductor device as illustrated in FIG. 1 is manufactured. This process is called a PE-ALD method using RLSA.

Here, in the gas adsorption process, it may be possible to form a small-volume region above the mounting table 34, particularly, above the processing target substrate W held thereon, and to perform the gas adsorption process in this small-volume region. In such a case, there may be prepared a gas supply device including a head unit. By way of example, the head unit has a size capable of covering the processing target substrate W and can be positioned above the mounting table 34. The head unit is configured to supply a film forming gas onto the processing target substrate W. In a gas supply process, by moving the head unit to a position above the mounting table 34 on which the processing target substrate W is held, a small-volume region smaller than the entire processing chamber 32 is formed. Then, the film forming gas is supplied into the small-volume region between the mounting table 34 and the head unit, and a pressure within the small-volume region is set to be as specified in step (A) of Table 1.

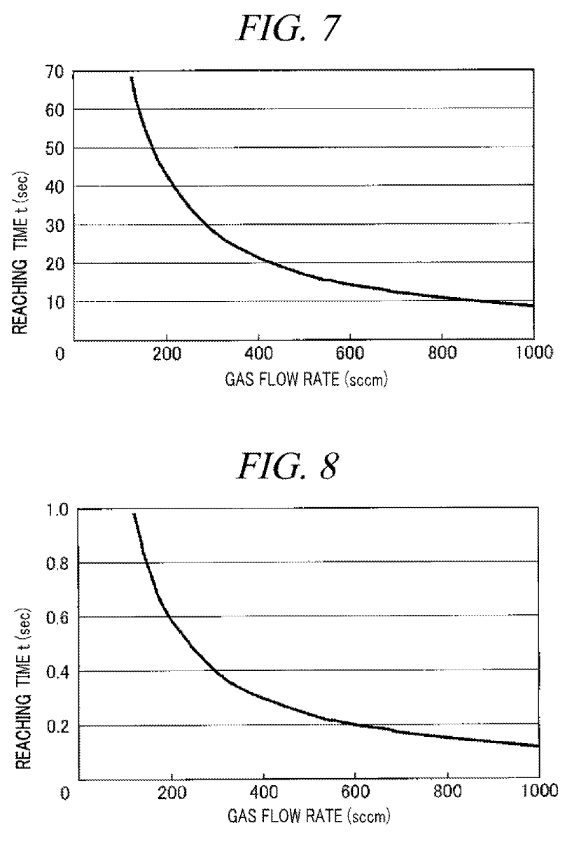

Now, a pressure control when using such a gas supply device will be explained. FIG. 7 is a graph showing a relationship between a gas flow rate and time required to reach a preset pressure in the entire processing chamber. FIG. 8 is a graph showing a relationship between a gas flow rate and time to reach a preset pressure in the small-volume region between the mounting table 34 and the head unit. In each of FIGS. 7 and 8, a vertical axis represents time (sec) and a horizontal axis represents a gas flow rate (sccm). Further, a gas flow rate is calculated in term of an Ar (argon) gas. The graphs of FIGS. 7 and 8 represent a case where a pressure is increased from about 1 Torr to about 3 Torr. In the case of FIG. 7, an entire volume of the processing chamber 32 is about 54 liters. In the case of FIG. 8, a volume of the small-volume area formed between the mounting table 34 and the head unit is about 0.75 liters.

Referring to FIGS. 7 and 8, in the entire gas flow rate range, time required to reach about 3 Torr is found to be greatly shortened in the case of FIG. 8, as compared to the case of FIG. 7. That is, by using the gas supply device, throughput can be greatly improved. Moreover, since an inner wall surface of the processing chamber is not exposed to the film forming gas, a cleaning process for cleaning the inner wall surface of the processing chamber can be omitted or simplified. Further, a problem of particle generation due to a reaction product of the film forming gas deposited on the inner wall surface of the processing chamber can also be reduced. In this configuration, in order to perform the plasma process efficiently, it may be desirable that the head unit is retreated to a position different from the position above the mounting table 34 in the plasma process.

In the plasma process, it may be desirable that a pressure within the processing chamber is set to be as low as possible. To be specific, the pressure within the processing chamber may be set to be equal to or lower than about 200 mTorr. By setting the pressure in this low range, a higher-quality film can be formed. Meanwhile, in the microwave plasma process, a process is performed at a pressure of several hundreds of mTorr, higher than a pressure for an ICP process or the like. In the ICP process, plasma is generated at a pressure ranging from about several mTorr to about several tens of mTorr. By performing the plasma process under such a higher pressure condition, throughput can be improved very efficiently.

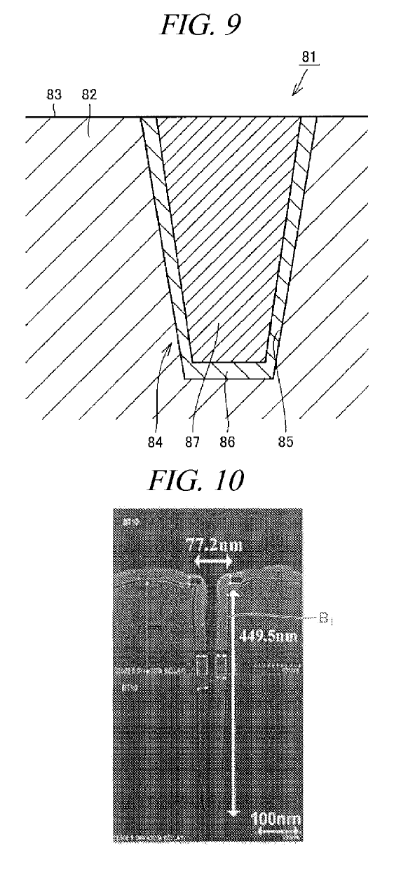

The above-described film forming method may be effectively applicable to a case of forming a liner film at a STI (Shallow Trench Isolation) as a device isolation region formed at a semiconductor device. FIG. 9 is an enlarged cross sectional view illustrating a vicinity of the STI.

As shown in FIG. 9, a STI 81 is formed by forming a groove called a trench in a downward direction from a main surface of a silicon substrate and filling the trench with an insulating member.

A process of forming the STI 81 will be described specifically. A groove-shaped trench 84 is formed downward from a certain position of a main surface 83 of the silicon substrate 82. Then, the trench 84 is filled with insulating member having insulation property. Through this process, the STI 81 is formed.

In this case, in order to improve insulation property at an interface between the silicon substrate 82 and the insulating member filled in the trench 84, an insulating layer of silicon oxide called a liner film 86 is formed on a surface 85 of the trench 84. Then, the trench 84 is filled with a filling film 87 having insulation property. The liner film 86 is required to have high insulation property and high step coverage. The film forming method in accordance with the illustrative embodiment can also be effectively used to form this liner film 86.

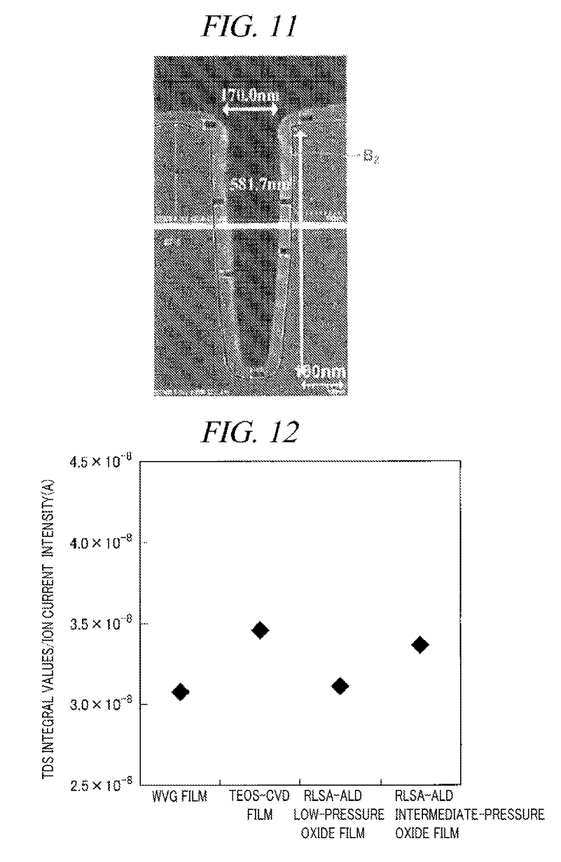

FIG. 10 is a micrograph showing an enlarged view of a liner film formed by PE-ALD method using RLSA when a trench has an aspect ratio of about 6. FIG. 11 is a micrograph showing an enlarged view of a linear film formed by PE-ALD method using RLSA when a trench has an aspect ratio of about 3. A portion marked by an arrow B₁ in FIG. 10 and a portion marked by an arrow B₂ in FIG. 11 correspond to the liner film shown in FIG. 9. In FIG. 10, since a width of a trench is about 77.2 nm and a depth of the trench is about 449. 5 nm, an aspect ratio of this trench is about 5.8. In FIG. 11, since a width of a trench is about 170 nm and a depth of the trench is about 581.7 nm, an aspect ratio of this trench is about 3.4.

Referring to FIGS. 10 and 11, in both cases where the aspect ratios are 6 and 3, the trenches are found to be completely covered by the liner films, and the liner films are found to be formed on the deepest portions of the trench.

Now, quality of a film formed by the film forming method as described above will be explained. FIG. 12 is a diagram showing TDS (Thermal Desorption Spectroscopy) integral values of H₂O (water) in various films. These various films include, as comparison targets, a WVG film formed by a WVG (Water Vapor Generator) at about 950° C.; a TEOS-CVD film formed by a TEOS gas (tetraethoxysilane gas) by microwave plasma CVD method using RLSA; a RLSA-ALD low-pressure oxide film formed through low-pressure oxidation by PE-ALD method using RLSA; and a RLSA-ALD intermediate-pressure oxide film formed through intermediate-pressure oxidation by a PE-ALD method using RLSA. A vertical axis indicates a TDS integral value of a desorption gas amount in a temperature range from about 25° C. to about 800° C. as an ion current intensity (A). If this value is low, it implies that an amount of impurities in a film is small and the quality of the film is high. Here, the low-pressure oxide film refers to an oxide film formed under the condition where a pressure within the processing chamber is about 150 mTorr, and the intermediate-pressure oxide film refers to an oxide film formed under the condition where the pressure within the processing chamber is about 380 mTorr. Further, in a plasma process on the RLSA-ALD low-pressure oxide film and the RLSA-ALD intermediate-pressure oxide film, the temperature of the mounting table is set to be in the range of about 300° C. to about 370° C.

Referring to FIG. 12, an integral value of a desorption gas amount of the WVG film is about 3.0×10⁻⁸, and an integral value of a desorption gas amount of the RLSA-ALD low-pressure oxide film is almost equivalent to that of the WVG film. Further, an integral value of a desorption gas amount of the RLSA-ALD intermediate-pressure oxide film is higher than about 3.0×10⁻⁸ and lower than about 3.5×10⁻⁸. In comparison, an integral value of a desorption gas amount of the TEOS-CVD film is about 3.5×10⁻⁸. That is, the RLSA-ALD low-pressure oxide film has high quality, substantially same as the WVG film, and the RLSA-ALD intermediate-pressure oxide film has higher quality than the TEOS-CVD film.

FIG. 13 is a diagram showing etching rate ratios of the films when about 0.5% of HF (hydrofluoric acid) is used. In FIG. 13, a vertical axis represents an etching rate ratio (A/min). Providing that impurities such as carbon are not included in a film, it is considered that the film has higher quality as its etching rate becomes lower.

In FIG. 13, an etching rate of the WVG film is lowest, i.e., about 20. Etching rates of the RLSA-ALD low-pressure oxide film and the RLSA-ALD intermediate-pressure oxide film are both over about 30. Meanwhile, an etching rate of the TEOS-CVD film is larger than about 35. From this graph, the RLSA-ALD films are found to have higher film quality than the TEOS-CVD film.

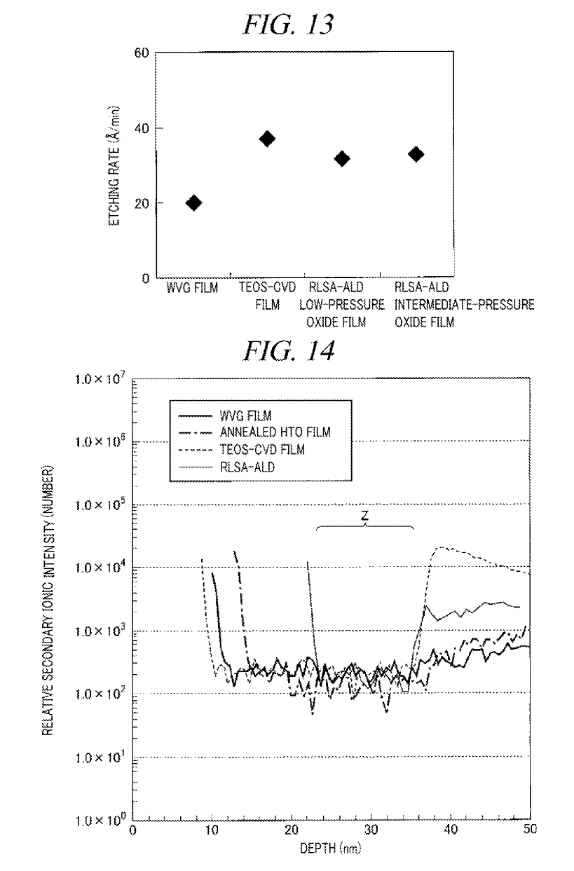

FIG. 14 is a graph showing Q-SIMS (Quadrupole-Secondary Ion Mass Spectrometry) values of the films. In FIG. 14, a vertical axis represents a relative secondary ionic intensity (number), and a horizontal axis represents a depth (nm) from a surface of a film. In FIG. 14, a region of each film in a depth direction thereof is indicated by a region Z. As can be seen from the graph, carbon is not mixed in any films.

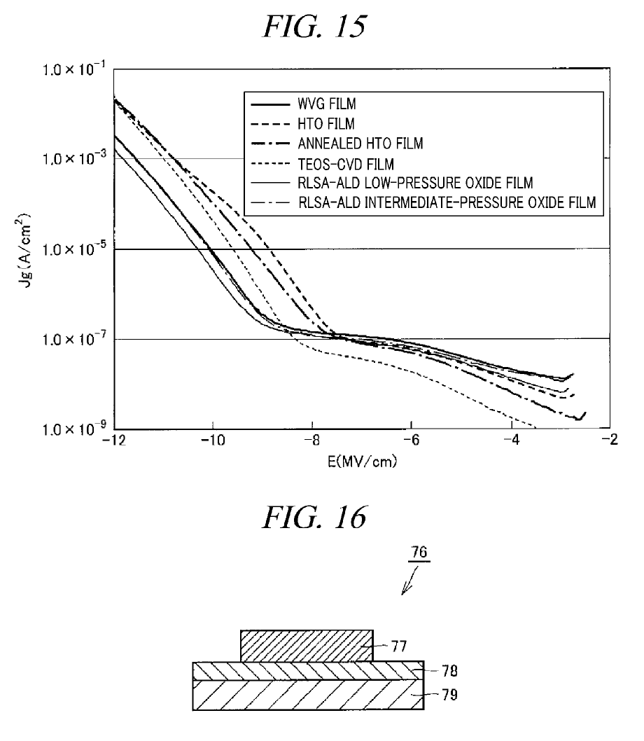

FIG. 15 is a graph showing so-called I-V curves in the films which are obtained by using a flat MOS. Here, a configuration of the flat MOS will be described briefly. FIG. 16 is a schematic cross sectional view illustrating the flat MOS. As depicted in FIG. 16, a flat MOS 76 includes a poly electrode layer 77 as an uppermost layer, a gate oxide film 78 as an intermediate layer and a silicon substrate 79 as a lowermost layer. By using this flat MOS 76, I-V curves shown in FIG. 15 are obtained. FIG. 15 shows a current characteristic (J) when magnitude of an applied electric field is varied in a film thickness range of about 7 mm in terms of EOT. In FIG. 15, in addition to the RLSA-ALD low-pressure oxide film and the RLSA-ALD intermediate-pressure oxide film, the WVG film, a HTO (High Temperature Oxide) film formed at a temperature of about 780° C., an annealed HTO film annealed at about 900° C. in a nitrogen atmosphere for about 15 minutes and the TEOS-CVD film are added as comparison targets.

Referring to FIG. 15, when the magnitude of the electric field is lower than about −9 MV/cm, the current densities of the RLSA-ALD low-pressure oxide film and the RLSA-ALD low-pressure oxide film are substantially same as that of the WVG film, though those of the RLSA-ALD oxide films are slightly higher than that of the MVG film. However, the current densities of the RLSA-ALD low-pressure oxide film and the RLSA-ALD intermediate-pressure oxide film are much lower than those of the HTO film, the annealed HTO and the TEOS-CVD film. That is, from the I-V curves, it can be also found that the RLSA-ADL films have high film qualities.

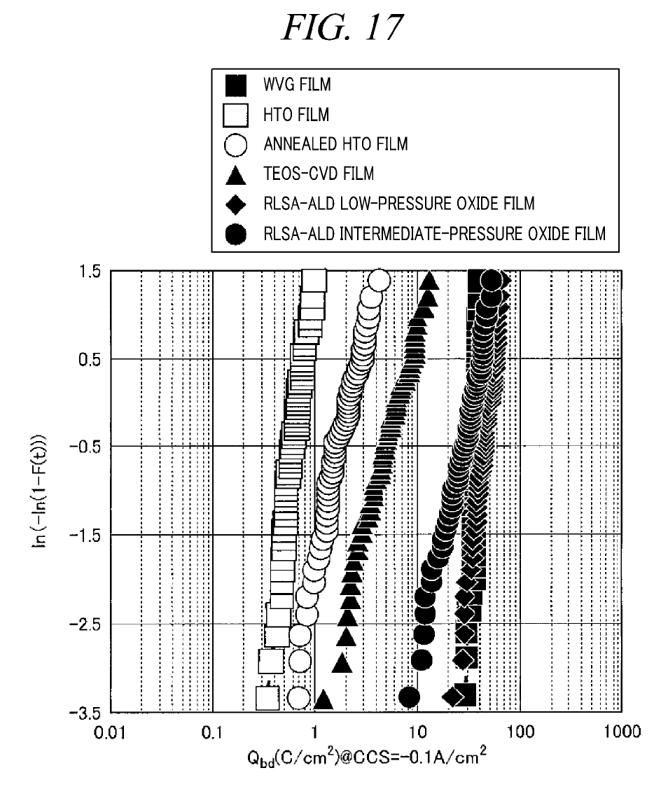

FIG. 17 is a graph showing Weibull plots of Qbd of the films. FIG. 17 provides Weibull plots of measurements results of Qbd (C/cm²) (CCS (Constant Current Stress)=−0.1 A/cm²). As shown in FIG. 17, plotted values of the RLSA-ALD low-pressure oxide film are substantially same as those of the WVG film, and from a value of about −1.5, at least from a value of about −0.5 on a vertical axis, Qbd value of the RLSA-ALD low-pressure oxide film is found to be higher than that of the WVG film. Further, the graph of the RLSA-ALD low-pressure oxide film has a vertically extending straight line shape, which indicates that the RLSA-ALD low-pressure film has high film quality. Plotted Qbd value of the RLSA-ALD intermediate-pressure oxide film is also found to be higher than that of the WVG film from a value of about 0 on the vertical axis. Further, the graph of the RLSA-ALD intermediate-pressure oxide film also has a vertically extending straight line shape. That is, from the graph of FIG. 17, it is also proved that the RLSA-ALD films have high film qualities.

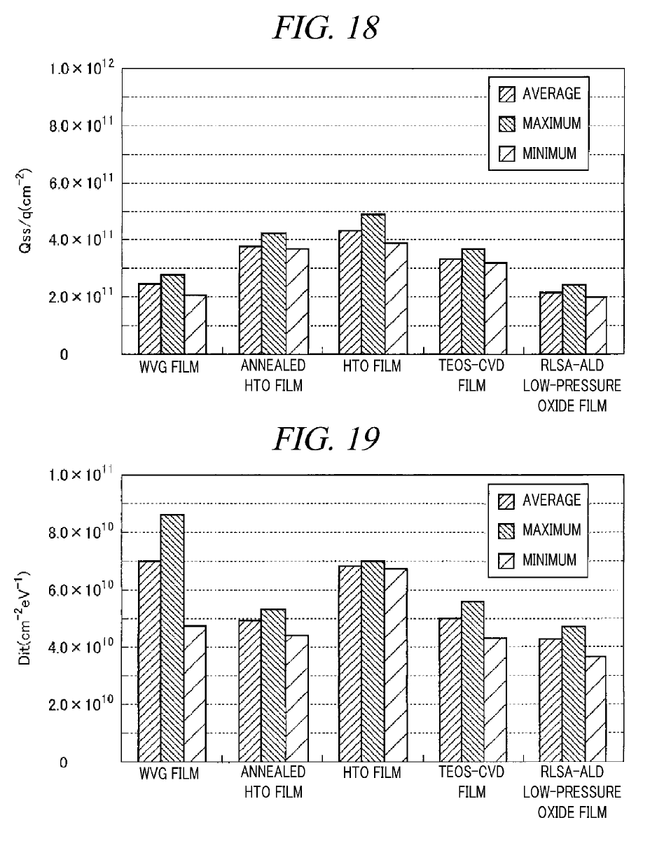

FIG. 18 is a graph showing calculated values of fixed electrical charge densities (Qss/q)(cm⁻²) in the WVG film, the HTO film, the annealed HTO film, the TEOS-CVD film and the RLSA-ALD low-pressure oxide film. For the calculation of the fixed electrical charge density in each film, a sample is prepared by forming a N⁻ polysilicon electrode on a to-be-tested insulating film deposited on a Si substrate and then performing, on the N⁺ polysilicon electrode, a H₂ sintering process (about 400° C.) which is used in an actual LSI manufacturing process. Then, two types of C-V measurements, i.e., high frequency CV measurement and QSCV (Quasi-Static CV) measurement are performed on the sample, and the Qss/q values are obtained by comparing the C-V measurement values with theoretical C-V curves. FIG. 18 shows an average value, a maximum value and a minimum value of the Qss/q values of each film. A high Qss/q value implies that an amount of fixed electrical charges in a film is great and, thus, electric leakage is highly likely to occur. As can be seen from FIG. 18, the Qss/q values of the HTO film are highest, and the Qss/q value of the WVG film is found to be good. Here, an average value of the fixed electrical charge density (Qss/q) in the RLSA-ALD low-pressure oxide film is about 2.1×10¹¹ (cm⁻²), and a maximum value thereof is about 2.4×10¹¹ (cm⁻²). That is, the fixed electrical charge density (Qss/q) in the RLSA-ALD low-pressure oxide film is lower than about 2.5×10¹¹(cm⁻²), and both a maximum value and a minimum value thereof are lower than those of the WVG film. Thus, the RLSA-ALD low-pressure oxide film has high leakage characteristic.

FIG. 19 is a graph showing interface state densities (Dit) (cm⁻²eV⁻¹) obtained in the respective films shown in FIG. 18. As a Dit value of a film is lower, it indicates that the film has higher leakage characteristic and has high film quality. As shown in FIG. 19, a difference between a maximum value and a minimum value of Dit value of the WVG film is great, and the Dit value of the WVG film is not better than that of the HTO film. Meanwhile, a difference between a maximum value and a minimum value of Dit value of the RLSA-ALD low-pressure oxide film is small and the Dit value of the RLSA-ALD low-pressure oxide film is small. To be specific, even the maximum value of the interface state density (Dit) (cm⁻²eV⁻¹) of the RSLA-ALD low-pressure oxide film is lower than about 5.0×10¹⁰ (cm⁻²eV⁻¹). Accordingly, it is found out that the RLSA-ALD film has high film quality in terms of the interface state density (Dit).

In accordance with the film forming method as described above, even if a processing target substrate has a shape having a high aspect ratio or a microscopic step-shaped portion of about 50 nm, it is possible to form a film so as to completely cover the shape by adsorbing a film forming gas on the processing target substrate and forming an adsorption layer on the processing target substrate. Further, since a plasma process is performed by microwave plasma, plasma damage can be greatly reduced in a film forming process. Accordingly, in accordance with the film forming method of the illustrative embodiment, it is possible to form a high-quality film.

Further, in accordance with the film forming method of the illustrative embodiment, it is possible to form a silicon oxide film having high insulation property in a semiconductor device at a low temperature. Accordingly, problems such as limitation on an order of manufacturing processes can be avoided.

Moreover, the insulating film formed by the present film forming method has high insulation property.

In addition, since the semiconductor device having the insulating film formed by the present film forming method has high insulation property, the semiconductor device has high quality.

In the above-described illustrative embodiment, it has been described that it is desirable that the pressure within the processing chamber is set to be as low as possible, to be specific, equal to or lower than about 200 mTorr. In consideration of TZDB (Time Zero Dielectric Breakdown), however, it may be possible that the pressure within the processing chamber is set to be an intermediate level of about 380 mTorr, e.g., equal to or lower than about 400 mTorr. That is, there is provided a film forming method for forming a film on a processing target substrate. The film forming method includes a gas adsorption process for forming an adsorption layer on the processing target substrate by adsorbing a film forming gas on the processing target substrate; and a plasma process for performing a plasma process on the adsorption layer by microwave plasma after the gas adsorption process. Here, the plasma process may be performed at a pressure equal or lower than about 400 mTorr.

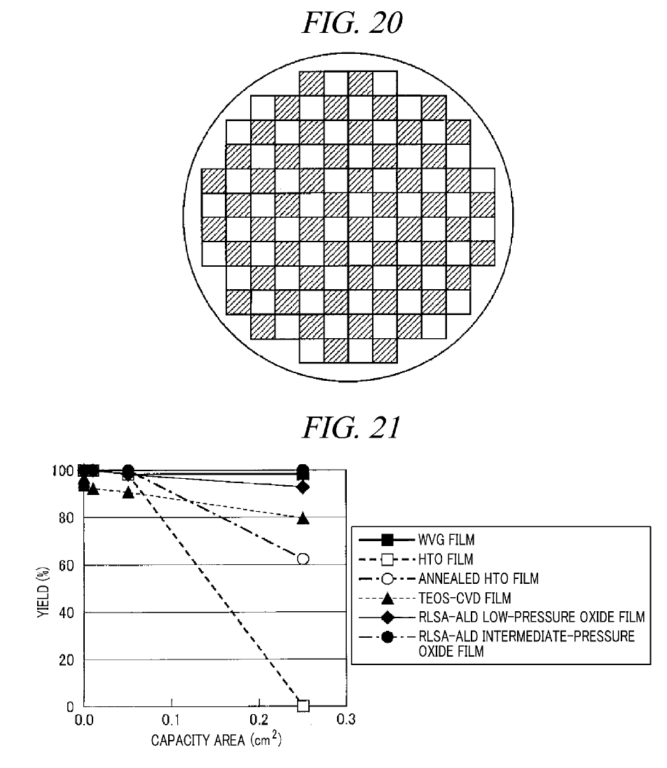

Such a film forming method will be explained in further detail. FIG. 20 shows measurement positions of TZDB in the flat MOS capacitor shown in FIG. 16. The measurement positions are 56 hatched regions in FIG. 20.

FIG. 21 is a graph showing TZDB characteristics of films when the regions shown in FIG. 20 are measured. In FIG. 21, a vertical axis represents a yield (%) and a horizontal axis represents a capacitor area (cm²), i.e., an area where the flat MOS capacitor is formed. The TZDB characteristics of FIG. 21 are obtained by applying an electric field of about −9 MV/cm as an dielectric breakdown electric field in a flat MOS capacitor having a film thickness of about 73 Å. Under this condition, it is determined that dielectric breakdown has occurred when a current density (Jg) is equal to or higher than about 1.0×10⁻³ A/cm². Here, a yield represents a ratio of the number of the measurement positions without suffering dielectric breakdown to the total number of the measurement positions. Practically, a capacitor area is much smaller than a level indicated by the horizontal axis of the graph of FIG. 21. By way of non-limiting example, the capacitor area may have a length and a width of about 40 nm×about 40 nm.

As shown in FIG. 21, even when the capacitor area is increased to about 0.25 cm², a yield of the WVG film is about 100%. Likewise, even when the capacitor area is increased to about 0.25 cm², a yield of the RLSA-ALD intermediate-pressure oxide film is about 100%. That is, in terms of TZDM characteristic, the WVG film and the RLSA-ALD intermediate-pressure oxide film are substantially same. As for the RLSA-ALD low-pressure oxide film, a yield thereof is higher than about 90%, and the yield thereof is higher than a yield of at least the TEOS-CVD film. Further, when the capacitor area is about 0.25 cm², a yield of the HTO film is about 0, and a yield of the annealed HTO film is about 60%.

The reason for the above is considered to be as follows. If there is a COP (Crystal Originated Particle) on a substrate as a base on which a film is formed, dielectric breakdown may occur at the COP portion. Here, in accordance with the film forming method of the illustrative embodiment, it is possible to securely form a film by ALD method even on the COP portion which is a very small area. Further, it is possible to form a film so as to almost completely cover the substrate as the base on which the film is formed. As a result, the TZDB characteristic may be improved.

The film forming method as described above can be effectively used when high insulation property is required in a relatively large area such as a gate insulating film. That is, a film forming gas is adsorbed on the processing target substrate so that an adsorption layer is formed. Then, a plasma process is performed on the adsorption layer by microwave plasma at a pressure equal to or lower than about 400 mTorr. As a result, an insulating film as a gate insulating film formed on a processing target substrate is formed. Such an insulation film has very high insulation property.

Further, in the above-described illustrative embodiment, the mounting table may be configured to be movable at least one of in a vertical direction and in a left-right direction. With this configuration, a gas adsorption process can be more efficiently performed. By way of example, in the gas adsorption process, a volume of a region above the mounting table may be reduced by moving up the mounting table. By performing the gas desorption process in this configuration, a supply amount of the film forming gas can be reduced, and a pressure control can be performed in a short period of time. Accordingly, efficiency of the gas adsorption process can be improved. In such a case, a plasma process may be performed after the mounting table is moved downward and positioned in the plasma diffusion region.

Moreover, if the plasma processing apparatus has the gas supply device including the head unit described above, the microwave plasma may be maintained generated all the time. In the gas adsorption process, a gas is adsorbed after moving the head unit above the mounting table. Meanwhile, in the plasma process, after the head unit is retreated from the region above the mounting table and the processing target substrate is positioned in the plasma diffusion region, the plasma process may be performed. With this configuration, throughput can be more improved.

Furthermore, in the above-described illustrative embodiment, the first exhaust process between the gas adsorption process and the plasma process, or the second exhaust process after the plasma process can be omitted, if necessary.

Furthermore, although the above-described illustrative embodiment has been described for the case of forming a silicon oxide film by performing a plasma process on the adsorption gas layer with oxygen radicals, the illustrative embodiment is not limited thereto but can also be applied to, e.g., forming a nitride film by performing a plasma process on the adsorption gas layer with nitrogen radicals. That is, the illustrative embodiment is also applicable to a process where after the above-described gas adsorption process, a gas containing a nitride, e.g., a N₂ gas is supplied into the processing chamber, and a plasma process is performed to thereby form a silicon nitride film.

Further, when forming a silicon nitride film as a nitride film, a gas containing a halogen compound of silicon such as Si₂Cl₆ (hexachlorodisilane) or SiH₂Cl₂ (dichlorosilane) may be used as a film forming gas. Furthermore, the plasma process may be performed by using a nitrogen-containing gas such as a N₂ gas or a NH₃ gas.

Furthermore, in the above-described illustrative embodiment, although a gas containing BTBAS is used as a film forming gas, a gas containing silicon may be used instead. Further, in the plasma process, a gas other than an oxygen gas may be used.

Further, although the illustrative embodiment has been described for the case of forming a trench in a device isolation region and forming a liner film on a surface of the trench before the trench is filled with a filling film having insulation property, the illustrative embodiment is not limited thereto. By way of example, the illustrative embodiment can be applied to forming, e.g., a gate oxide film or another insulating film such as an interlayer insulating film or a gate sidewall in a MOS transistor. Besides, the illustrative embodiment is also effectively applicable in a CCD, a LSI, and so forth. That is, the illustrative embodiment is applicable to all kinds of film forming processes performed by combining a gas adsorption process for forming an adsorption layer by supplying a film forming gas on a processing target substrate and a plasma process by microwave plasma.

Examples of specific films are mentioned below. By way of non-limiting example, SiO₂, Al₂O₃, HfO₂, ZrO₂, Ta₂O₅, La₂O₃ may be formed as a gate insulating film; SiO₂, HfO₂, Al₂O₃, Ta₂O₅ may be formed as a trench capacitor of a DRAM (Dynamic Random Access Memory); SiO₂, Al₂O₃, HfO₂, ZrO₂, Ta₂O₅, La₂O₃ may be formed as a gate oxide film of a 3D device such as a FinFET (Field Effect Transistor); HfO₂, Ta₂O₅, TiO₂, Ta₂O₅, Al₂O₃ may be formed as a nanolaminate of MEMS (Micro Electro Mechanical Systems); ZnO, TiO₂ may be formed as a UV block layer; Al₂O₃ as an alumina insulating film may be formed as an organic EL (Electro Luminescence) element; AlTiO, SnO₂, ZnO may be formed as an optical device, a solar cell or the like; and ZnO may be formed as a piezoelectric sensor.

Further, in the above-described illustrative embodiment, the silicon oxide film is formed and the plasma process is performed in the same plasma processing chamber. However, the silicon oxide film forming process and the plasma process may be performed in separate processing chambers.

Furthermore, in the above-described illustrative embodiment, the plasma process is performed by microwave by using RLSA including a slot antenna plate. However, the plasma process may be performed by a microwave plasma processing apparatus using a comb-shaped antenna.

Furthermore, in the above-described illustrative embodiment, the plasma process is performed by using microwave plasma having an electron temperature lower than about 1.5 eV and an electron density higher than about 1×10¹¹ cm⁻³. However, the illustrative embodiment is not limited thereto and is also applicable to a plasma density range lower than about 1×10¹¹ cm⁻³.

The above illustrative embodiment has been described for the case of forming an insulating film such as a silicon oxide film, but the illustrative embodiment is not limited thereto and may also be applicable to forming a conductive film. The present illustrative embodiments have been explained by reference to the drawings, but the present illustrative embodiment is not limited thereto. The illustrative embodiments can be changed and modified in various ways within the same or equivalent scope of the present illustrative embodiments.

### INDUSTRIAL APPLICABILITY

A film forming method, a semiconductor device manufacturing method, an insulating film and a semiconductor device in accordance with the illustrative embodiments may be effectively used when high insulation property and high step coverage are required.

### EXPLANATION OF CODES

11: MOS semiconductor device

12, 79, 82: Silicon substrate

13, 81: Device isolation region

14a: p-well

14b: n-well

15a: High-concentration n-type impurity diffusion region

15b: High-concentration p-type impurity diffusion region

16a: n-type impurity diffusion region

16b: p-type impurity diffusion region

17, 78: Gate oxide film

18: Gate electrode

19: Gate sidewall

21: Insulating film

22: Contact hole

23: Buried electrode

24: Metal wiring layer

26, 27: Region

31: Plasma processing apparatus

32: Processing chamber

33, 46, 47: Plasma processing gas supply unit

34: Mounting table

35: Microwave generator

36: Dielectric window

37: Slot antenna plate

38: Dielectric member

39: Plasma generating device

40: Slot hole

41: Bottom portion

42: Sidewall

43: Gas exhaust hole

44: Cover

45: O-ring

48: Bottom surface

49: Gas supply system

50: Gas supply hole

51: Cylindrical supporting member

53: Matching device

54: Mode converter

55: Waveguide

56: Coaxial waveguide

57: Recess

76: Flat MOS

77: Poly electrode layer

83: Main surface

84: Trench

85: Surface

86: Liner film

87: Filling film

1. A film forming method for forming a film on a processing target substrate, the method comprising:
a gas adsorption process for forming an adsorption layer on the processing target substrate by adsorbing a film forming gas on the processing target substrate; and
a plasma process for performing a plasma process on the adsorption layer by microwave plasma after the gas adsorption process.

2. The film forming method of claim 1,
wherein the film is an insulating film.

3. The film forming method of claim 1,
wherein the gas adsorption process includes a process for adsorbing a film forming gas containing silicon atoms on the processing target substrate.

4. The film forming method of claim 3,
wherein the gas adsorption process further includes a process for supplying a film forming gas containing BTBAS (bis-tertiaryl-buthyl-amino-silane) onto the processing target substrate.

5. The film forming method of claim 1,
wherein the plasma process includes a process for performing an oxidation or a nitrification on the adsorption layer formed through the gas desorption process by plasma.

6. The film forming method of claim 1,
wherein the microwave plasma is generated by a radial line slot antenna (RLSA).

7. The film forming method of claim 1,
wherein the plasma process is performed by the microwave plasma having an electron temperature lower than about 1.5 eV and an electron density higher than about 1×10¹¹ cm⁻³ in a vicinity of a surface of the processing target substrate.

8. The film forming method of claim 1,
wherein the plasma process is performed at a pressure equal to or lower than about 200 mTorr.

9. The film forming method of claim 1,
wherein the gas adsorption process includes a process for forming the adsorption layer after adjusting a volume of a region above the processing target substrate.

10. The film forming method of claim 1, further comprising:
an exhaust process for evacuating a region above the processing target substrate between the gas adsorption process and the plasma process.

11. The film forming method of claim 1, further comprising:
an exhaust process for evacuating a region above the processing target substrate after the plasma process.

12. A semiconductor device manufacturing method including a film forming method for forming a film on a processing target substrate,
wherein the film forming method includes:
a gas adsorption process for forming an adsorption layer on the processing target substrate by adsorbing a film forming gas on the processing target substrate; and
a plasma process for performing a plasma process on the adsorption layer by microwave plasma after the gas adsorption process.

13-17. (canceled)

18. A film forming method for forming a film on a processing target substrate, the method comprising:
a gas adsorption process for forming an adsorption layer on the processing target substrate by adsorbing a film forming gas on the processing target substrate; and
a plasma process for performing a plasma process on the adsorption layer by microwave plasma after the gas adsorption process,
wherein the plasma process is performed at a pressure equal or lower than about 400 mTorr.

19. (canceled)
